(19) United States
(12) Patent Application Publication
(10) Pub. No.: US 2002/0050829 A1
(43) Pub. Date: May 2, 2002

(54) Thyristor linked inductor

(76) Inventor: Wilsun Xu, Edmonton (CA)

Correspondence Address: C. A. ROWLEY, P. O. BOX 59, 51 RIVERSIDE PARKWAY, FRANKFORD, ON, K0K 2C0, CA

(21) Appl. No.: 09/933,897

(22) Filed: Aug. 22, 2001

Related U.S. Application Data
(60) Provisional application No. 60/228,413, filed on Aug. 29, 2000.

(51) Int. Cl. G05F 1/24; G01R 27/28

(52) U.S. Cl. 324/654

(57) ABSTRACT

A thyristor linked inductor is formed by a plurality of inductor segments connected in series, each inductor segment including a coil, a first switch in series with the coil, a shunt for by-passing the coil and a second switch for controlling the shunt. It is important that each of the first and second switches in each inductor segment be formed by a pair of thyristors connected in anti-parallel relationship.

### RELATED APPLICATIONS

Applicant claims the benefits under USC 35 §119 (e) based on Provisional application No. 60/228,413 filed Aug. 29, 2000.

### FIELD OF INVENTION

The present invention relate to an improved form of variable inductor.

### BACKGROUND OF THE INVENTION

Variable inductors can be found in many industrial applications. The main applications are power quality and efficiency improvement, for instance, voltage regulation, power factor correction and flicker control. Another potential application of a variable inductor is a tunable harmonic filter. With more harmonic currents present in the modem power systems, an effective and economical measure of mitigating harmonics is in high demand. Great efforts have been made in constructing a variable inductor branch, which lead to several types of devices. These devices are playing important roles in many industrial applications. Some variable inductors, such as the variable air-gap type inductor, tap-changing inductor and dc premagnetized type inductor, have been patented. However, these devices suffer from certain drawbacks such as the necessity of mechanical operation, slow time response and high cost. This has led to the development of static arrangements using thyristor switches. Thyristor-controlled variable inductors which are free from the drawbacks mentioned above have been developed; however, their main disadvantage is the harmonic distortion of the input current, particularly at delayed firing angles.

An inductor is usually composed of a coil and a core. Considering a solenoid core, the inductance can be represented as:

$$L = \frac{μ {N}^{2} A}{l} \qquad ( 2.1 )$$

where

μ is the permeability of the material of the core.

N is the number of turns carrying current around the coil.

A is the cross sectional area of the coil.

l is the length of the coil.

Two methods can be derived from Equation 2.1 to realize a variable inductor. One is through the change of μ, which results in a flux controllable inductor; the other is varying the number of turns.

The material of the core also plays an important role in inductance. The core is usually made of ferromagnetic material, such as iron, which shows the effect of saturation. Therefore, when the inductor is working in the saturated region, the relationship between the flux density B and field intensity H is non-linear, referred to in equations as:

H=KI (2.3)

B=f(H)

λ=NBA (2.4)

where

K is a constant related to the structure of the coil and the material of the core,

N is the number of turns of the coil.

B=f(H) is the nonlinear magnetization characteristic of the device.

Then, the relationship between λ and I is non-linear. Consequently, the inductance is inherently changeable. This kind of variable inductor is known as a saturable inductor. Another way to achieve a variable inductor is to use an electronic component to control the current applied to the inductor; the most widely used one is the thyristor-controlled reactor (TCR).

An extensive survey on variable inductors shows that the existing devices fall into four basic categories: saturable or flux controllable inductor, electronic switch controlled inductor, winding turns changeable inductor and tapped inductor.

Saturable or Flux Controllable Inductor

A saturable inductor exploits the effect of saturation of ferromagnetic material. In its simplest form a saturable inductor comprises two coils mounted on the same core; one is the main coil and the other is a control coil. An additional variable DC source is necessary to supply the control coil. With the change of the DC current, the flux in the core is also changed, so the saturation degree of the core can be controlled by the control coil. The inductance of the main coil will change accordingly.

It is obvious that this inductor has a non-linear response since it works in the saturated region. In turn, it will generate harmonics that is not favorable to the system. The core losses are high due to the amount of stored energy, and the variation range is low because of its working region.

A flux changeable inductor uses mechanical devices to control either the number of flux linkages of the inductor or the reluctance of the magnetic circuit passing through the coils. The number of flux linkages is altered mechanically by using a tapped inductor coil and a tap-changing mechanism, which is a relay-controlled motor. Altering, again mechanically, the reluctance of the coil is achieved by controlling the movement of a low reluctance material within the inductor. A typical example is shown in U.S. Pat. No. 4,347,489, which uses a hand crank to move an iron core into a current carrying coil.

An electrical way to change the permeability of the core and, hence, to change flux linkage is realized using two orthogonally placed cores (see U.S. Pat. No. 4,393,157). The two cores intersect in two areas. One core carries an alternative magnetic field, and the other circulates an adjustable direct current magnetic field. The change of direct current alters the permeability of the intersecting regions, and in this way the overall permeability of the core and therefore the inductance of the alternating current coil. This type of device requires extra equipment in the form of additional DC source and has a limited variable range.

Electronic Switch Controlled Inductor

The most widespread electronic switch controlled inductor is the thyristor-controlled reactor (TCR). It is mainly employed in shunt static VAR or reactive power compensators. In its simplest form a TCR comprises a pair of thyristor T₁ and T₂ connected in anti-parallel relationship i.e. the thyristors are in parallel but are arranged so that one permits current flow in one direction and the other in the opposite direction when they are triggered to open position. The pair of thyristors is connected in series with an inductor coil. When one of the thyristor T₁ is fired at θ₁ and the other thyristor T₂ is fired at θ₂(=180+θ₁), the resulting input current contains all odd harmonics among which the third harmonic is predominant. As θ₁ is varied, the fundamental component of input current varies in magnitude, so the impedance of the inductor at fundamental frequency is equivalently changed.

The main disadvantage of TCR is harmonic generation. It is designed only for fundamental frequency applications, i.e., it is a variable inductor only at fundamental frequency. At harmonic frequencies, it behaves as harmonic sources do.

Switched Inductor

The switched-inductor formed by providing a switch in series with the inductance coil and a second switch in a shunt by-passing the coil. These devices are intended to solve the harmonic problem of TCR. Both the switches are self-commutated bi-directional switches with complementary gatings. Through high-frequency switching, the fundamental component of the inductor current i_{L} can be controlled by changing the duty cycle of the switches.

The currents are fairly smooth, which means the low order harmonics are effectively eliminated, but the system requires high frequency switches, which results in high switch losses, a complex control strategy and its use is limited to being a variable inductor at fundamental frequency.

Coil Turns Changeable Inductor

The principle of operation of this inductor is very simple: namely, change the inductance by changing the number of turns of the coil. One such system employs triac switches, which are bidirectional triode thyristors that can conduct both directions of current flow in response to a positive or negative gate signal positioned to include or exclude coils from operation. By operation of the switches, the effective number of turns of secondary winding is changed. Therefore the inductance seen from is changed accordingly. In this case, the inductance is linearly varied causing no distortion to the supply current. This makes it superior to other existing devices.

Its disadvantage lies in the operation of its secondary winding. When one of the switches is forward biased, part of the coil is short-circuited. The switch conducts the short circuit current. When the switch is reverse-biased, it has to block the induced voltage across the winding. This device suffers from high switch current stress and switch voltage stress.

Tapped Inductor

This kind of variable inductor is sometimes termed as a tap-changing inductor. As the name indicated, the inductance can be varied by changing the tap connection on a coil. It is seen in the application of the furnace power supply and it is also used as a voltage regulator.

In these systems the switches generally are triacs or back to back thyristors. When a different switch is closed, the total inductance seen from the terminal is different. In this case, only one switch can be closed at one time. The inductance of this kind of variable inductor can be changed linearly, however, this device produces high voltage stress on switches and larger step of variation.

With more and more load equipment sensitive to power quality variation installed in the power systems, the drawbacks of the existing variable inductors are more manifested and their further application is limited. Hence, a better performing variable inductor is in high demand.

### BRIEF DESCRIPTION OF THE PRESENT INVENTION

It is the main object of this invention to provide an improved form of variable inductor or reactor suitable for use in a variety of applications.

It is also the objective of this invention to provide an original scheme of applying a variable inductor.

Broadly the present invention relates to a thyristor linked inductor comprising a plurality of inductor segments connected in series, each said inductor segment including a coil, a first switch means in series with said coil, a shunt means for by-passing said coil and a second switch means for activating and deactivating said shunt means, each of said first and second switch means comprising a pair of thyristors connected in anti-parallel relationship.

Preferably said coil of each inductor segment is mount on a core common to other coils of other of said inductor segments.

Preferably said core is an iron core.

Preferably each said inductor segment has a pair of first switch means position one on each side of its said coil, said shunt means comprising a pair of shunts each incorporating a second switch means, one shunt of said pair of shunts being connected at its one end between said coil and one of said pair of first switch means and at its opposite end at the side of the other of said pair of first switch means remote from said coil and the other shunt of said pair of shunts being connected at its one end between said coil and said other of said pair of first switch means and at its opposite end at the side of said one of said pair of first switch means remote from said coil.

The present invention also relates broadly to series reactive power compensator comprising a capacitor in series with a variable inductor.

Preferable the variable inductor will be a thyristor linked inductor.

### BRIEF DESCRIPTION OF THE SEVERAL VIEWS OF THE DRAWING(S)

Further features, objects and advantages will be evident from the following detailed description of the preferred embodiments of the present invention taken in conjunction with the accompanying drawings in which;

FIG. 1A is a schematic illustration of the physical layout of a first configuration of one form of thyristor linked inductor or reactor (TLR) constructed in accordance with the present invention.

FIG. 1B is a schematic view showing all the coils (all of the inductor segments) inserted into the circuit.

FIG. 1C is a view similar to FIG. 1B but showing one the coils (top coil in the Figure) shunted out of the circuit.

FIG. 2: is a view similar to FIG. 1A illustrating the physical layout of a second configuration of a thyristor linked inductor constructed in accordance with the present invention.

FIG. 3 is a view similar to FIG. 1B wherein all the coils are inserted into the circuit in a normal way.

FIG. 4: is a view similar to FIG. 1C wherein on of the coils is shunted out.

FIG. 5: shows an arrangement wherein one of the coils is inserted at a negative polarity in the circuit, i.e. the current flowing in coil is in the opposite direction with respect to the currents in other coils.

FIG. 6 shows a series reactive power compensator (Series LC compensator) connected in shunt and is in parallel with a disturbance producing load such as a motor or an arc furnace.

### DETAILED DESCRIPTION OF THE INVENTION

The variable reactor or inductor of the present invention is called thyristor linked reactor (or inductor) sometimes referred to below as a TLR. It is implemented as will be described below by changing the number of the connected inductor segments in the circuit.

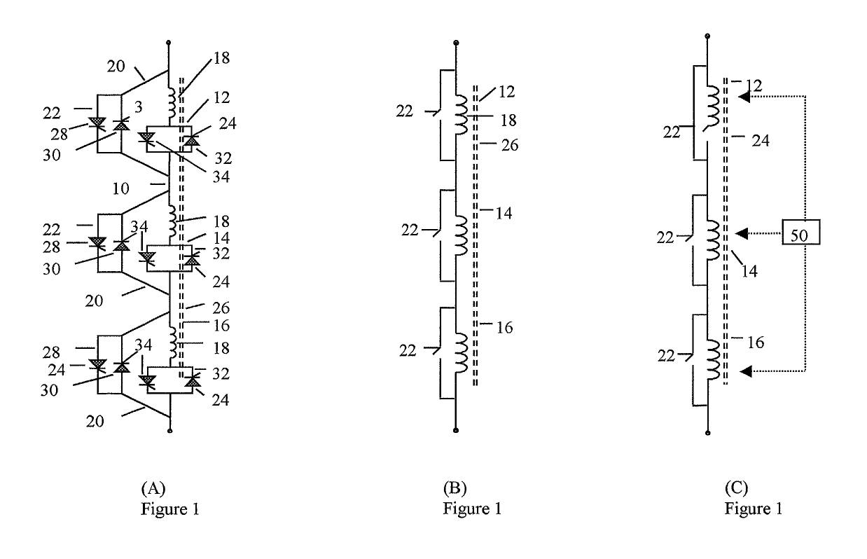

In the embodiment shown in FIG. 1A the TLR 10 is composed of a circuit that includes 3 separate inductor segment 12, 14 and 16 (more or fewer such segments may be used.) All the segments 12, 14 and 16 are essentially the same and each has a coil 18, a shunt 20 incorporating switch means 22 in parallel with coil 18, and a switch means 24 in series with the coil 18 of its segment.

The coils 18 of the inductor segments 12, 14 and 16 are mounted on the same inductor core 26. The core can be air-core or iron-core. There could also be no core, i.e. there is no coupling among the three coil parts 18 of the inductor segments 12, 14 and 16. In this case, these are three separate inductors 12, 14 and 16.

An important feature of this invention is that all coils may be mounted in one structure so that there is only one physical component. For example the segments could be arranged in a straight line as shown in FIG. 1A or the core could be formed into a loop and the coils 18 of the inductor segments be positioned around the loop in the form of a rectangle or square with a separate coil encircling each side of the rectangle or square. i.e. a TLR with 4 segments would be formed.

The switch means 22 and 24 are each formed by a thyristor pair connected in anti-parallel. The thyristors forming the switch means 22 and indicated at 28 and 30 and those forming the switch means 24 at 32 and 34. By connecting each pair of thyristors 28 and 30 and the pair 32 and 34 in anti-parallel relationship, triggering the thyristor gates simultaneously in any of the switch means 22 or 24 will allow current to flow in either direction. After the triggering signal is removed, the thyristor keeps conducting until the current becomes zero. The thyristors 28, 30, 32 and 34 thus act as switches. By controlling the operation of the thyristors 28, 30, 32 and 34, the individual inductor segment 12, 14 and 16 can be either included or shunted out (bypassed).

FIG. 1B shows all of the switches 24 in conducting position and all of the switches 22 in non-conducting condition so that the coils 18 of all of the inductor segments 12, 14 and 16 are connected in series. Hence the total inductance of the circuit is larger.

FIG. 1C shows the switch 22 of segment 12 in conducting condition and the switch 24 of segment 12 in non-conducting position so that the coil 18 of the segment 12 is shunted out of the circuit i.e. is by-passed. Thus in this arrangement there are less coils 18 in the total circuit. Hence the total inductance of the circuit is smaller.

It will be apparent that by selectively controlling the switches 22 and 24 of the segments 12, 14 and 16 the total inductance of the system may be varied substantially. A suitable computer or other type of controller as schematically indicated at 50 in FIG. 1C and the dashed control lines interconnecting the controller 50 with each of the switches 22 and 24 in each of the segments 12, 14 and 16 may be used to control the operation of these switch means 22 and 24. It will be apparent that in this embodiment of the invention when switch mean 22 is closed in one segment the corresponding switch means 24 in that segment is open and vice versa.

This arrangement will result in a linearly variable reactor at all frequency ranges with the following advantages over other types:

The structure is simple; no auxiliary dc source is needed.

The inductor does not generate harmonics, so no additional filters are needed.

It has smooth transient performance.

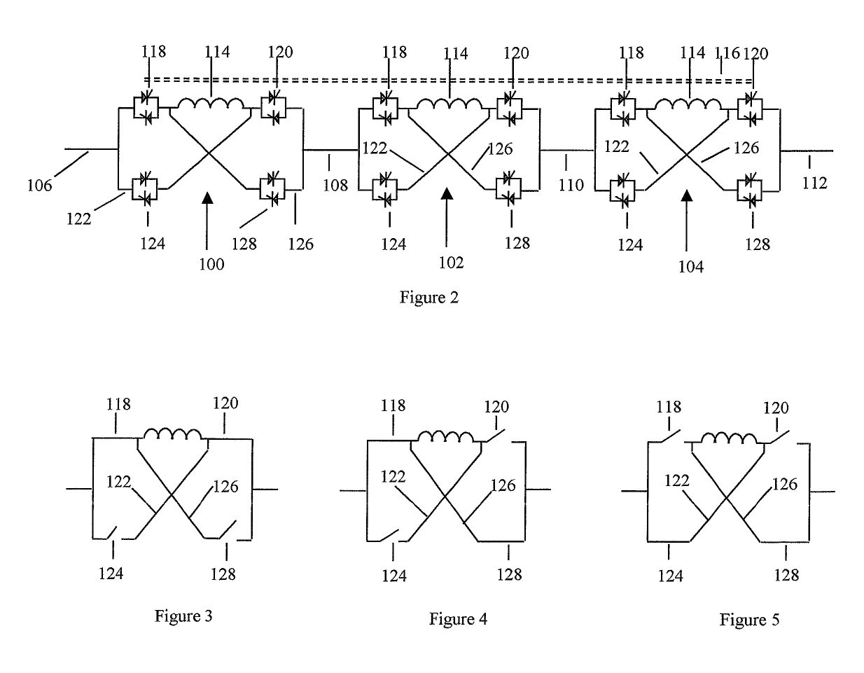

Turning now to FIG. 2 a second operating configuration of the TLR of the present invention has been shown. In this arrangement

3 inductor segments 100, 102 and 104 (more or less may be used as desired) have been shown in connected in series by an incoming (or out going) connectors 106, connectors 108 and 110 and an out going (or incoming) conductor 112. All of the segments are essentially the same and each is composed of a coil 114 all of which preferably are wound on a common core 116 equivalent to the core 26 described above in connection with the FIG. 1 embodiment of the invention.

A switch means 118 and 120 are positioned one at each end of their respective coils 114 in each of the segments 100, 102 and 104. Referring to the inductor segment 100 (the other segments are essentially the same) the incoming switch means 118 (assuming 106 is an incoming line) is interposed between the incoming line 106 and its coil 114 and the out going switch means 120 is interposed between its coil 114 and the outgoing line for segment 100 assuming 106 is an incoming line then 108 is the out going line. Obviously if the line 108 becomes the incoming line then the switch means 120 will be the incoming switch means and the switch means 118 will be the out-going switch means.

A first shunt circuit 122 forms a shunt around coil 114 from the incoming line 106 to the side of the coil 114 remote from the incoming line 106 and connects to the circuit of the inductor segment 100 (or 102 or 104 ) between the end of the coil 114 and the out going switch means 120. This shunt 122 has a switch means 124 to open or close the shunt circuit 122. A second shunt circuit 126 forms a shunt around coil 114 from the outgoing line 108 to the side of the coil 114 remote from the outgoing line 108 and connects to the circuit of the inductor segment 100 (or 102 or 104 ) between the end of the coil 114 and the incoming switch means 118. This shunt 126 has a switch means 128 to open or close the shunt circuit 126. Similar parts have been indicated with like reference numerals in each of the inductor segments 100, 102 and 104.

The switch means 118, 120, 124, and 128 are each constructed essentially the same as the switch means 22 and 24 and thus are each formed by a thyristor pair connected in anti-parallel as described in more detail above with respect to the switch means 22 and 24.

The operation of the system or configuration of Figure will be evident from FIG. 3, 4 and 5 which various switching conditions that may selectively be applied to each of the inductor segments 100, 102 and 104. In FIG. 3: the incoming and out going switches 118 and 120 are closed, and the switch means 124 and 126 are open. In this case, the coil 114 of the segment (100, 102 or 104 ) is inserted into the circuit in a normal way.

In FIG. 4 the switch means 120 and 118 and 126 are closed, and switch means 120 and 124 are open. In this case, the coil part 114 is bypassed. The total inductance of the segment 100, 102 or 104 is smaller.

FIG. 5 shows the switch means 118 and 120 open and the switch means 124 and 126 closed. In this case, coil part 114 is inserted at a negative polarity, i.e. the current flowing in 114 is in the opposite direction with respect to the currents in other coil parts. As a result, the total flux is reduced even more and the total inductance is the smallest among the three operating modes illustrated in FIG. 3, 4 and 5.

It will be apparent that a suitable controller such as that illustrated at 50 in the FIG. 1 embodiment may be provided to control the operation of the switch means 118, 120, 124 and 126 of each of the inductor segments 100, 102, 104, etc. that for the complete inductor.

It will be apparent from the above that some of the key characteristics of the present invention are

The method of coil-bypassing. By bypassing certain number of coils 18 or 114 using anti-parallel thyristors as the switch means the inductance of the device can be changed. The result is a variable inductor.

The inductance of the TLR of the present invention may be varied from 0 to Lₘₐₓ. This is quite different from the TCR (Thyristor-Controlled Reactor) characteristics where the inductance varies from Lₘᵢₙ to infinite.

Another significant difference with the TCR of the present invention is that the inductor is linear for all frequencies—a genuine variable inductor and is harmonic free.

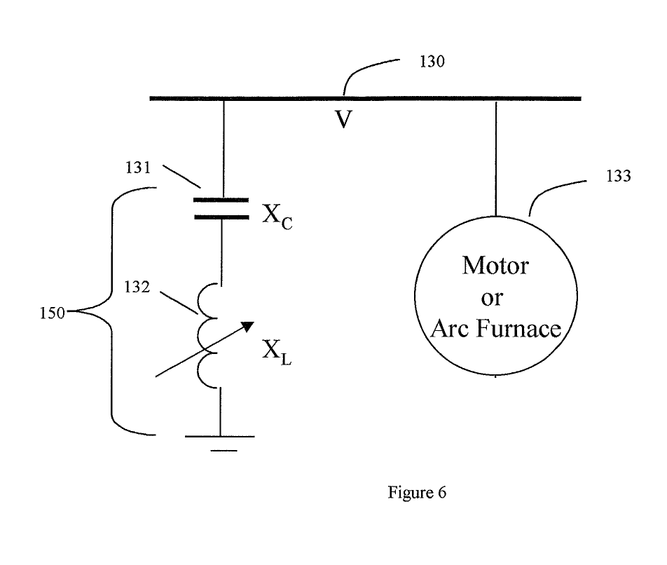

The series reactive power compensator (series LC compensator) 150 of the present invention (see FIG. 6) has a capacitor 131 in series with a variable inductor 132. This series connected LC device 150 is in the arrangement shown in FIG. 6 connected to a bus 130. The bus 130 has a voltage V. Also connected to the bus 130 is a fluctuating load 133, such as motor or arc furnace that causes undesirable fluctuations of the bus voltage V. The series LC compensator 150 can inject variable reactive power into the system and thereby reduce the amount of voltage fluctuation. The total capacitive impedance of the compensator 150 is

X_{C-total}=X_{C}−X_{L}

where

X_{C} is the reactance of the capacitor 131 and

X_{L} is that of the inductor 132.

The reactive power or var output of the compensator is

Q=V²/X_{C-total}=V²/(X_{C}−X_{L})

It can be seen that the output Q can be varied by changing X_{L} from 0 to X_{Lmax}. When X_{L}=0, the device output least amount of var. When X_{L}=X_{Lmax}, it outputs maximum amount of var. This new compensator 150 has the following advantages 1) the variable component (X_{L}) only experiences a portion of the line voltage V and 2) the capacitor (X_{C}) can be overloaded temporarily.

As a result, the device 150 may be less expensive than other types of compensators. This device 150 could be used for example for 1) motor starting support, 2) var source for induction generators and other distributed generators, and 3) other regular applications offered by existing var compensators.

In the preferred form of the invention the variable inductor 132 will be a thyristor linked reactor (or inductor) as described above in connection with FIGS. 1 and 2.

The a thyristor linked inductor of the present invention may be applied to a wide variety of different application such as those outlined below.

1. Tunable Harmonic Filter and Adaptive Harmonic Filters

In this application, the variable inductor (series LC compensator of the present invention) is put in series with a capacitor to form a passive harmonic filter. The tuning frequency of the filter is determined according to

$$f = \frac{1}{2 π \sqrt{L C}}$$

where C is the capacitance and L is the inductance. A variable inductor can change the inductance value and thereby change the tuning frequency of the filter. In the first version of this application, the inductor can make small variations in its inductance. The filter tuning frequency can then be adjusted to compensate its drift due to the variation of component parameters. Component parameter variations are caused by factors such as temperature change, failure of capacitors in a bank, deviation from design parameters.

A more interesting application is the adaptive harmonic filter bank. In this case, a group of identical passive filters with the TLR as variable inductors are used to construct a filter bank. Inductors of the filters can make large variations. For example, a filter's tuning frequency can be changed from one harmonic to another, say, from the 5th to 7th harmonic. These filters have some ‘intelligence’ to adjust their tuning frequencies independently and collectively so that users don't need to worry about the frequencies to which they should be tuned. A group of filters, once installed, would be able to figure out among themselves the best combination of their tuning frequencies. Since the filters are identical. Manufacturing cost will be low.

2. Variable Grounding Reactor for Resonant Grounded Systems

In this application, the reactor or inductor is connected at the grounding point of a substation transformer. Impedance of the reactor can be varied to limit the single-phase to ground fault current in the distribution system. For systems with long distribution lines or cables, there could be large amount of phase-to-ground charging capacitance. The capacitance could sustain the arcing current of single-phase to ground faults. A neutral inductor with a proper size could cancel out the capacitance (i.e. in resonant with the capacitance), resulting in almost zero arcing current. The main difficulty of this application is that the neutral reactor must be variable in order to compensate the (variable) capacitance. Variation of the capacitance is normally caused by different network configurations. The inductor of the present invention can also serve as a variable grounding reactor.

Having described the invention, modifications will be evident to those skilled in the art without departing from the scope of the invention as defined in the appended claims.

We claim:

1. A thyristor linked inductor comprising a plurality of inductor segments connected in series, each said inductor segment including a coil, a first switch means in series with said coil, a shunt means for by-passing said coil and a second switch means for activating and deactivating said shunt means, each of said first and second switch means comprising a pair of thyristors connected in anti-parallel relationship.

2. A thyristor linked inductor as defined in claim 1 wherein said coil of each inductor segment is mount on a core common to other coils of other of said inductor segments.

3. A thyristor linked inductor as defined in claim 2 wherein said core is an iron core

4. A thyristor linked inductor as defined in claim 1 wherein each said inductor segment has a pair of first switch means position one on each side of its said coil, said shunt means comprising a pair of shunts each incorporating a second switch means, one shunt of said pair of shunts being connected at its one end between said coil and one of said pair of first switch means and at its opposite end at the side of the other of said pair of first switch means remote from said coil and the other shunt of said pair of shunts being connected at its one end between said coil and said other of said pair of first switch means and at its opposite end at the side of said one of said pair of first switch means remote from said coil.

5. A thyristor linked inductor as defined in claim 4 wherein said coil of each inductor segment is mount on a core common to other coils of other of said inductor segments.

6. A thyristor linked inductor as defined in claim 5 wherein said core is an iron core

7. A series reactive power compensator comprising a variable inductor connected in series with a capacitor

8. A series reactive power compensator as defined in claim 7 connected in parallel with a fluctuating load.

9. A series reactive power compensator as defined in claim 7 wherein said variable inductor is thyristor linked inductor.

10. A series reactive power compensator as defined in claim 8 wherein said variable inductor is thyristor linked inductor.
